(19) United States
(12) Patent Application Publication
(10) Pub. No.: US 2009/0189296 A1
(43) Pub. Date: Jul. 30, 2009

(54) FLIP CHIP QUAD FLAT NON-LEADED PACKAGE STRUCTURE AND MANUFACTURING METHOD THEREOF AND CHIP PACKAGE STRUCTURE

(75) Inventors: Cheng-Ting Wu, Tainan County (TW); Hung-Tsun Lin, Tainan County (TW); Yu-Ren Chen, Tainan County (TW); Chun-Ying Lin, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHIPMOS TECHNOLOGIES INC., Hsinchu (TW)

(21) Appl. No.: 12/275,172

(22) Filed: Nov. 20, 2008

(30) Foreign Application Priority Data
Jan. 30, 2008 (TW) 97103470
Jan. 30, 2008 (TW) 97103472
Feb. 20, 2008 (TW) 97105932

(51) Int. Cl. H01L 23/52; H01L 21/00

(52) U.S. Cl. 257/778; 438/108; 257/E21.001; 257/E23.141

(57) ABSTRACT

A manufacturing method for a Flip Chip Quad Flat Non-leaded package structure is provided. A lead frame having a plurality of leads is provided at first in the manufacturing method. A dielectric layer is formed on the lead frame and exposes a top surface and a bottom surface of the leads. A redistribution layer including a plurality of pads and a plurality of conductive lines connected the pads and the top surface of the leads is formed on the dielectric layer. A solder resist layer is formed to cover the redistribution layer, the dielectric layer and the leads, and expose the surface of the pads. An adhesive layer is formed on the solder resist layer. A chip having a plurality of bumps is provided. The chip is adhered on the solder resist layer with the adhesive layer and each bump is electrically connected with one of the pads.

### CROSS-REFERENCE TO RELATED APPLICATION

This application claims the priority benefits of Taiwan applications of serial no. 97103472, filed on Jan. 30, 2008, serial no. 97103470, filed on Jan. 30, 2008 and serial no. 97105932, filed on Feb. 20, 2008. The entirety of each of the above-mentioned patent applications is hereby incorporated by reference herein and made a part of this specification.

### BACKGROUND OF THE INVENTION

1. Field of the Invention

The present invention generally relates to a package structure and a manufacturing method thereof. More particularly, the present invention relates to a flip chip quad flat non-leaded (QFN) package structure and manufacturing method thereof, and a chip package structure for enhancing the efficiency of the devices.

2. Description of Related Art

In semiconductor industry, production of integrated circuit (IC) is mainly divided into three stages: IC design, IC process and IC package. The package may prevent the chip from influence of external temperature and humidity, and from contamination of dust, and may provide an intermedium for connecting the chip to external circuits.

There are a lot of package types in the semiconductor fabrication industry. In recent years, the quad flat non-leaded (QFN) packages have a shorter average trace so that signal transmission speed is faster. As a result, quad flat non-leaded package has become one of the main options for fabricating a high frequency (for example, radio frequency bandwidth) chip package with a low pin count.

Nevertheless, the conventional QFN package structures are used for wire bonding to electrically connect a chip to a carrier. Here, the carrier is, for example, a lead frame of a package substrate. However, the QFN type is high-cost and bulky.

Besides, the chip pads of the conventional QFN packages are electrically and directly connected to the leads via bumps, and therefore the size of the flip chip QFN package structures are sure to the size of the leads of the lead frame, and it is difficult to reduce the production cost by using smaller size chip. However, the size of the current chip achieves miniaturization, so the solution of how to use the smaller size chip to form the QFN package structure and how to make the QFN package structure more compact are highly desired in the technology of IC package.

Further, since the leads of the QFN package structure during the cutting process in the pertinent art, the metallic element is existed in the cutting channels, resulting in a decrease of lifespan of a cutting tool. Therefore, the solution of how to increase the lifespan of the cutting tool is desired in the QFN package structure.

Furthermore, the chip is disposed on the circuit board by using flip-chip bonding and the chip and the pads are located in two side of the circuit board. Hence, when the chip electrically connected to the circuit board via the bumps, the electric transmitting rate between the chip and the circuit board will be influenced by the long length of the wire. Therefore, the efficiency of the devices will be influenced.

### SUMMARY OF THE INVENTION

The present invention is directed to a manufacturing method of a flip chip quad flat non-leaded package structure having reduced the thickness of the package and improved convenience of the manufacturing process.

The present invention is further directed to a flip chip quad flat non-leaded package structure, wherein the chip having different arrangement of the pads can be used via designing the dielectric layer and the redistribution layer. Further, the QFN package structure is formed by using the smaller size of the chip and accordingly the production cost will be reduced.

The present invention is further directed to a flip chip quad flat non-leaded package structure, wherein the size of the package substrate can be reduced via designing the dielectric layer, the redistribution layer and the supplementary substrate and the package substrate can apply in different types of the chip.

The present invention is further directed to a chip package structure having increased an electric transmission speed between the chip and the substrate.

The present invention is further directed to a chip package structure having enhanced the efficiency of the devices.

In order to achieve the above object, the present invention provides a manufacturing method of a flip chip quad flat non-leaded package structure, which includes the following steps. First, a lead frame having a plurality of lead is provided. Next, a dielectric layer is formed on the lead frame. The dielectric layer exposes a top surface and a bottom surface of the leads. Next, a redistribution layer is formed on the dielectric layer. The redistribution layer includes a plurality of pads and a plurality of conductive lines connected the pads and the top surface of the leads. Next, a solder resist layer is formed to cover the redistribution layer, the dielectric layer and the leads, and expose the surface of the pads. Then, an adhesive layer is formed on the solder resist layer. After that, a chip having a plurality of bumps is provided. The chip is adhered on the solder resist layer via the adhesive layer and each bump is electrically connected with one of the pads.

According to an embodiment of the present invention, the manufacturing method of a flip chip quad flat non-leaded package structure further includes a molding compound. The molding compound covers the chip, the solder resist layer and the dielectric layer and fills a space formed by the chip and the solder resist layer. The molding compound exposes the bottom surface of the leads. In one embodiment of the present invention, the manufacturing method of a flip chip quad flat non-leaded package structure further includes forming at least a through hole in the dielectric layer. The pads of the redistribution layer are formed around the through hole and the solder resist layer exposes the through hole. In another embodiment of the present invention, the molding compound fills the through hole.

According to an embodiment of the present invention, the molding compound covers the side of the leads.

According to an embodiment of the present invention, a material of the adhesive layer comprises epoxy resin or B-stage adhesive.

According to an embodiment of the present invention, the thickness of the dielectric layer is smaller than or equal to the height of the leads.

According to an embodiment of the present invention, the lead frame further includes a frame. The leads are connected with the frame and arranged along the center of the frame and extending to an array or a single row.

The present invention further provides a flip chip quad flat non-leaded package structure. The flip chip quad flat non-leaded package structure including a dielectric layer, a plurality of the leads, a redistribution layer, a solder resist layer, an adhesive layer and a chip is provided. The leads are disposed in the dielectric layer and expose a top surface and a bottom of the leads. The redistribution layer is disposed on the dielectric layer, and the redistribution layer includes a plurality of pads and a plurality of conductive lines connected the pads and the top surface of the leads. The solder resist layer covers the redistribution layer, the dielectric layer and the leads, and exposes the surface of the pads. The adhesive layer is disposed on the solder resist layer. The chip has a plurality of bumps, and the chip is adhered on the solder resist layer via the adhesive layer, and each bump is electrically connected with one of the pads.

According to an embodiment of the present invention, the flip chip quad flat non-leaded package structure further includes a molding compound. The molding compound covers the chip, the solder resist layer and the dielectric layer and fills a space formed by the chip and the solder resist layer. The molding compound exposes the bottom surface of the leads. In one embodiment of the present invention, the dielectric layer has at least a through hole and the solder resist layer exposes the through hole. Furthermore, the molding compound is disposed in the through hole.

According to an embodiment of the present invention, the molding compound covers the side of the leads.

According to an embodiment of the present invention, the surface of the dielectric layer is aligned with the top surface of the leads, and the thickness of the dielectric layer is smaller than or equal to the height of the leads.

According to an embodiment of the present invention, the flip chip quad flat non-leaded package structure further includes a frame. The leads are connected with the frame and arranged along the center of the frame and extending to an array or a single row.

The present invention further provides a manufacturing method of a flip chip quad flat non-leaded package structure, which includes the following steps. First, a supplementary substrate is provided. Next, a plurality of leads is formed on the supplementary substrate. Next, a dielectric layer is formed to cover the supplementary substrate and expose at least a top surface of the leads. Next, a redistribution layer is formed on the dielectric layer. The redistribution layer includes a plurality of pads and a plurality of conductive lines connected the pads and the top surface of the leads. Next, a solder resist layer is formed to cover the redistribution layer, the dielectric layer and the leads, and expose the surface of the pads. Then, an adhesive layer is formed on the solder resist layer. After that, a chip having a plurality of bumps is provided. The chip is adhered on the solder resist layer via the adhesive layer, and each bump is electrically connected with one of the pads.

According to an embodiment of the present invention, the manufacturing method of a flip chip quad flat non-leaded package structure further includes a molding compound. The molding compound covers the chip and the solder resist layer and fills a space formed by the chip and the solder resist layer. Furthermore, after the molding compound forming, the manufacturing method of a flip chip quad flat non-leaded package structure further includes removing the supplementary substrate to expose a bottom surface of the leads.

According to an embodiment of the present invention, a material of the supplementary substrate comprises polymer material or metal.

According to an embodiment of the present invention, the thickness of the dielectric layer is approximate to or equal to the height of the leads.

The present invention further provides a flip chip quad flat non-leaded package structure. The flip chip quad flat non-leaded package structure including a dielectric layer, a plurality of the leads, a redistribution layer, a solder resist layer, an adhesive layer and a chip is provided. The leads are disposed in the dielectric layer and expose a top surface and a bottom of the leads. The redistribution layer is disposed on the dielectric layer. The redistribution layer includes a plurality of pads and a plurality of conductive lines connected the pads and the top surface of the leads. The solder resist layer covers the redistribution layer, the dielectric layer and the leads, and exposes the surface of the pads. The adhesive layer is disposed on the solder resist layer. The chip has a plurality of bumps. The chip is adhered on the solder resist layer via the adhesive layer, and each bump is electrically connected with one of the pads.

According to an embodiment of the present invention, the flip chip quad flat non-leaded package structure further includes a molding compound. The molding compound covers the chip and the solder resist layer and fills a space formed by the chip and the solder resist layer.

According to an embodiment of the present invention, the top surface and the bottom surface of the dielectric layer is aligned with the top surface and the bottom surface of the leads.

According to an embodiment of the present invention, the leads are arranged in at least a ring or in an array.

According to an embodiment of the present invention, a material of the adhesive layer comprises epoxy resin or B-stage adhesive.

The present invention further provides a chip package structure. The chip package structure including a substrate, a chip, a plurality of bumps and a molding compound is provided. The substrate has at least an opening, a plurality of first pads and a plurality of ball pads. The first pads and the ball pads are disposed on the two opposite surface of the substrate respectively. The chip has an active surface and a plurality of second pads disposed on the active surface. The active surface of the chip is face to the substrate. The bumps are disposed between the first pads and the second pads and connected to the first pads and the second pads. The molding compound covers the chip and the bumps and fills the opening.

According to an embodiment of the present invention, the chip package structure further includes an adhesive layer. The adhesive layer is disposed between the chip and the substrate and surrounds the bumps.

According to an embodiment of the present invention, a material of the adhesive layer comprises B-stage adhesive.

According to an embodiment of the present invention, the chip package structure further includes a plurality of solder balls. The solder balls are disposed on the ball pads respectively.

The present invention further provides a chip package structure. The chip package structure including a lead frame comprising a plurality of leads, a chip, a plurality of bumps, an adhesive layer, a first molding compound and a second molding compound is provided. The lead frame comprising a plurality of leads has at least an opening between the leads. The chip has an active surface and a plurality of pads disposed on the active surface. The active surface of the chip is face to the leads. The bumps are disposed between the pads and the leads and connected to the pads and the leads. The adhesive layer is disposed between the leads and the chip and covers the bumps. The first molding compound is disposed in the opening. The second molding compound covers the chip and the adhesive layer.

According to an embodiment of the present invention, a material of the adhesive layer comprises B-stage adhesive.

Based on the above, according to the present invention, the chip is electrically connected to the redistribution layer and the leads via the dielectric layer and the redistribution layer formed above the dielectric layer. Here, the dielectric layer and the redistribution layer formed above the dielectric layer in the present embodiment must be capable of the same function of the substrate in the pertinent art. Thereby, the different types of the chip can be applied in the package structure. Another, the dielectric layer has through hole and accordingly the molding compound will uniformly distribute in the space, and therefore a batter bonding force between the molding compound, the chip and the dielectric layer can be increased. Further, the adhesive layer having B-stage characteristic is for fixing the chip, therefore the delivery process within the fabrication point is more convenient and the chip-lead frame package structure can be easily and efficiently fabricated. Furthermore, the package structure is used the flip chip technology instead of the wire bonding of the quad flat non-leaded package in the pertinent art, resulting in reduced package size, namely, reduced the thickness of the package.

Moreover, since the process of the fabrication has the supplementary substrate design, thereby realizing multiply leads and the array type of the package substrate. Further, since during the subsequent cutting process, the metal layer is not existed in the cutting channels, so that lifespan thereof can be prolonged.

Furthermore, the contact points for connecting the chip and the substrate (or the lead frame comprising a plurality of leads) are disposed in the same side of the substrate (or the lead frame comprising a plurality of leads), and the chip is electrically connected to the substrate (or the lead frame comprising a plurality of leads) via the bumps, and therefore the electrically connected route between the chip and the substrate (or the lead frame comprising a plurality of leads) is reduced, the transmitting rate between the chip and the substrate (or the lead frame comprising a plurality of leads) is improved, and the efficiency of the devices are enhanced.

In order to make the above and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views illustrating a manufacturing method of a flip chip quad flat non-leaded package structure according to an embodiment of the present invention.

FIG. 2 is a cross-sectional view of the structure depicted in FIG. 1B along a line I-I′.

FIG. 3 is a schematic view of a chip according to an embodiment of the present invention.

FIG. 4 is a cross-sectional view of the structure depicted in FIG. 1F along a II-II′.

FIGS. 5 through 10 are schematic cross-sectional views illustrating a manufacturing method of a flip chip quad flat non-leaded package structure according to an embodiment of the present invention. Herein, the sub-diagrams (a) for FIG. 5 through FIG. 10 are schematic top views of FIG. 5 through FIG. 10. The sub-diagrams (b) for FIG. 5 through FIG. 6 are schematic cross-sectional views depicted in the sub-diagrams (a) for FIG. 5 through FIG. 6 along the line I-I′. The sub-diagrams (b) for FIG. 7 through FIG. 10 are schematic cross-sectional views depicted in the sub-diagrams (a) for FIG. 7 through FIG. 10 along the line II-II′.

FIG. 11 is a schematic view of a chip according to an embodiment of the present invention.

FIG. 12 is a schematic cross-sectional view illustrating a flip chip quad flat non-leaded package structure according to an embodiment of the present invention.

FIG. 13 is a schematic cross-sectional view illustrating a chip package structure according to an embodiment of the present invention.

FIG. 14 is a schematic cross-sectional view illustrating a chip package structure according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

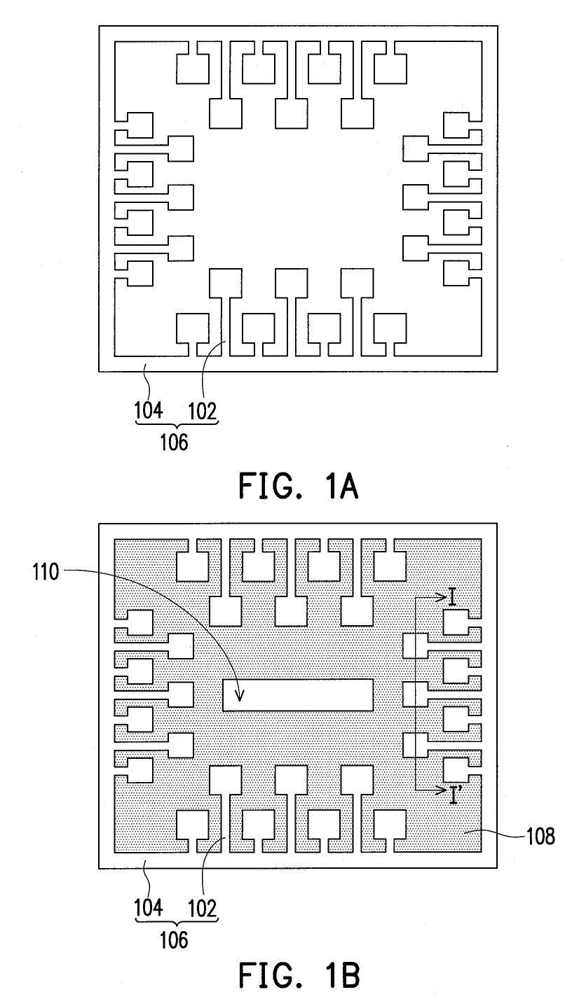

FIGS. 1A through 1F are schematic cross-sectional views illustrating a manufacturing method of a flip chip quad flat non-leaded package structure according to an embodiment of the present invention.

As shown in FIG. 1A, in a manufacturing method of a flip chip quad flat non-leaded package structure according to the present embodiment, which includes the following steps. A lead frame 106 having a plurality of lead 102 is provided at first. In the present embodiment, the lead frame 106 further includes a frame 104. The leads 102 of the lead frame 106 are connected with the frame 104 and arranged along the center of the frame 104 and extending to an array or a single row (not shown). For instance, the leads 102 can be arranged in both sides of the frame 104 or arranged in a ring around the frame 104.

A material of the lead frame 106 is, for example, copper, copper alloy, nickel-iron alloy or other applicable metal material. A method of forming the lead frame 106 includes the following steps. A metallic material layer is provided at first. Next, a patterning process and a photolithography and etching process for once are performed to pattern the metallic material layer. After that, the required pattern is formed.

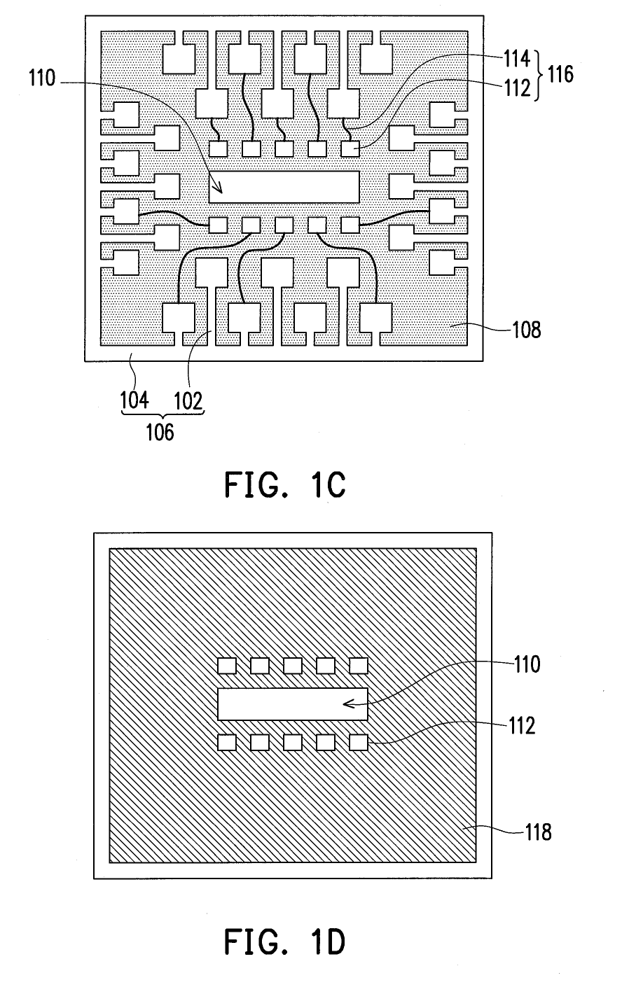

Next, referring to FIG. 1B, a dielectric layer 108 is formed on the lead frame 106. A material of the dielectric layer 108 is, for example, epoxy resin or other applicable dielectric material. FIG. 2 is a cross-sectional view of the structure depicted in FIG. 1B along a line I-I′. Referring to FIG. 2, a dielectric layer 108 exposes a top surface and a bottom surface of the leads 102. The thickness of the dielectric layer 108 is smaller than the height of the leads 102. However, in another embodiment of the present invention, the thickness of the dielectric layer 108 may be equal to the height of the leads 102. Besides, in one embodiment, at least a through hole 110 is formed in the dielectric layer 108. The through hole 110 is located, for example, around a region formed by the leads 102. For the convenience of description, only one through hole 110 is schematically depicted in the present embodiment.

Next, referring to FIG. 1C, a redistribution layer 116 is formed on the dielectric layer 108 to change the circuit layout of the external contacts on the chip. The redistribution layer 116 includes a plurality of pads 112 and a plurality of conductive lines 114 connected the pads 112 and the top surface of the leads 102. A method of forming the redistribution layer 116 is, for example, a sputtering process. In the present embodiment, a material of the redistribution layer 116 is, for example, copper or other applicable metal material. In one embodiment, the pads 112 of the redistribution layer 116 may be formed around the through hole 110. Moreover, the position and the arrangement of the pads 112 and the conductive lines 114 of the redistribution layer 116 as shown in this FIG. 1C are merely exemplificative and should not be construed as limitations to the present invention.

It should be noted that the dielectric layer 108 and the redistribution layer 116 formed above the dielectric layer 108 in the present embodiment must be capable of the same function of the substrate in the pertinent art. Therefore, the chip adhered for subsequently performing is electrically connected to the leads 102 of the lead frame 106 via the redistribution layer 116.

Next, referring to FIG. 1D, a solder resist layer 118 is formed to cover the redistribution layer 116, the dielectric layer 108 and the leads 102, and expose the surface of the pads 112 of the redistribution layer 116. In one embodiment, the through hole 110 is exposed in solder resist layer 118. A material of the solder resist layer 118 is, for example, epoxy resin. A method of forming the solder resist layer 118 is, for example, a coating process.

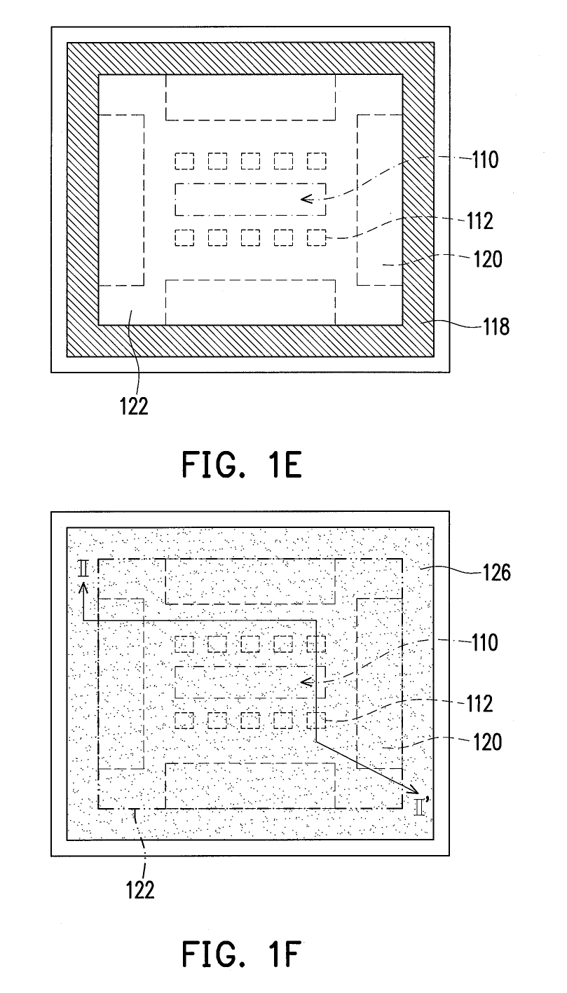

Next, referring to FIG. 1E, after forming the solder resist layer 118, an adhesive layer 120 is formed on the solder resist layer 118. A material of the adhesive layer 120 is, for example, epoxy resin, B-stage adhesive or other applicable adhesive material. After that, a chip 122 (as shown in FIG. 3) having the pads 123 disposed on is provided. The distribution of the pads 123 is, for example, peripheral pad or the central pad. In the present embodiment, the exemplificative distribution of the pads 123 merely has the central pad as illustrated in FIG. 3. The chip 122 has a plurality of bumps 124 on the active surface, and each bump 124 is formed on the pads 123 of the chip 122. A material of the bumps 124 is, for example, gold, copper, nickel, aluminium, tin, lead or an alloy of the above-mentioned metals. Furthermore, as shown in FIG. 1E, the chip 122 is flipped such that the active surface is face down. And then, the chip 122 is adhered on the solder resist layer 118 via the adhesive layer 120 and each bump 124 of the chip 122 is electrically connected with one of the pads 112 of the redistribution layer 116.

Specifically, in the present embodiment, the chip 122 is adhered on the stack structure formed with the solder resist layer 118, the redistribution layer 116, the dielectric layer 108 and the lead frame 106 via the adhesive layer 120 which is formed on the solder resist layer 118 and has B-stage characteristic. Therefore, the delivery process within the fabrication point is more convenient and the chip-lead frame package structure can be easily and efficiently fabricated. Besides, the chip having different arrangement of the pads can be used in the present invention by using the redistribution layer 116.

Further, in the present embodiment, the package structure is used the flip chip technology instead of the wire bonding of the quad flat non-leaded package in the pertinent art, resulting in reduced package size, namely, reduced the thickness of the package.

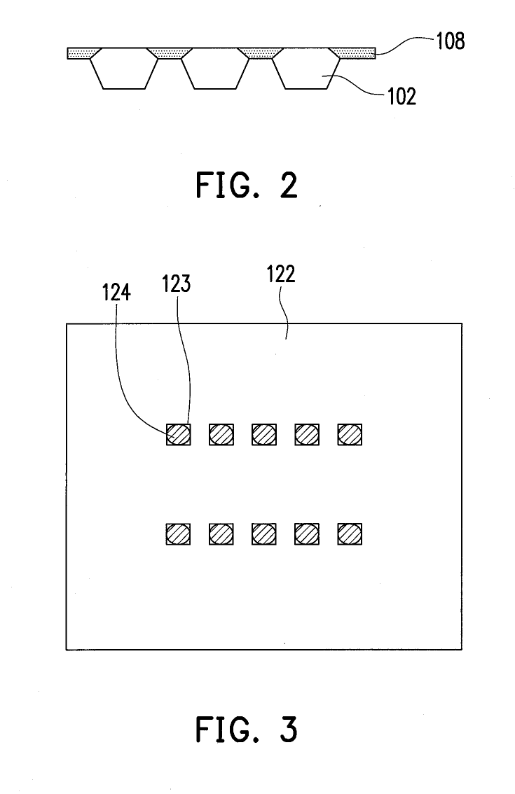

FIG. 4 is a cross-sectional view of the structure depicted in FIG. 1F along a II-II′. Next, referring to FIGS. 1F and 4, in a manufacturing method of a flip chip quad flat non-leaded package structure according to the present embodiment further includes a molding compound 126. The molding compound 126 covers the chip 122, the solder resist layer 118 and dielectric layer 108. The molding compound 126 is preferred to fill in a space 128 formed by the chip 122 and the solder resist layer 118. Further, the molding compound 126 exposes the bottom surface of the leads 102 of the lead frame 106. Another, the molding compound 126 covers the side of the leads 102. In one embodiment, the molding compound 126 fills the through hole 110 formed by the dielectric layer 108 and the solder resist layer 118 so as to uniformly distribute in the space and a batter bonding force between the molding compound 126, the chip 122 and the dielectric layer 108. A material of the molding compound 126 is, for example, epoxy resin or other applicable polymer material.

Next, with reference to FIGS. 1F and 4, a flip chip quad flat non-leaded package structure in the present invention is formed by the manufacturing method thereof, wherein the material and the manufacturing methods of each of the elements of the package structure have been described above, so the detailed description is not repeated.

In the present embodiment, the package structure includes the dielectric layer 108, the leads 102, the redistribution layer 116, the solder resist layer 118, the adhesive layer 120 and the chip 122 is provided, wherein the leads 102 are, for example, a frame 104 connected to the lead frame 106 formed in the present embodiment and the leads 102 are arranged along the center of the frame 104 and extending to array.

Furthermore, the leads 102 are disposed in the dielectric layer 108 and expose the top surface and the bottom surface of the leads 102. As shown in FIG. 2, the surface of the dielectric layer 108 is aligned with the top surface of the leads 102, and the thickness of the dielectric layer 108 is smaller than or equal to the height of the leads 102. In one embodiment, the dielectric layer 108 has at least a through hole 110.

Besides, the redistribution layer 116 is disposed on the dielectric layer 108 and the redistribution layer 116 includes a plurality of pads 112 and a plurality of conductive lines 114 (as shown in FIG. 1C). The solder resist layer 118 covers the redistribution layer 116, the dielectric layer 108 and the leads 102, and the solder resist layer 118 exposes the surface of the pads 112 of the redistribution layer 116. In one embodiment, the through hole 110 is exposed in the solder resist layer 118. The adhesive layer 120 is disposed on the solder resist layer 118. The adhesive layer 120 in the present invention has a B-stage characteristic, and therefore the process in the packaging is more convenient. The chip 122 has a plurality of bumps 124, and the chip 122 is adhered on the solder resist layer 118 via the adhesive layer 120, and each bump 124 is electrically connected with one of the pads 112 of the redistribution layer 116.

Furthermore, in a manufacturing method of a flip chip quad flat non-leaded package structure according to the present embodiment further includes a molding compound 126. The molding compound 126 covers the chip 122, the solder resist layer 118 and dielectric layer 108. The molding compound 126 is preferred to fill in a space 128 formed by the chip 122 and the solder resist layer 118. Further, the molding compound 126 exposes the bottom surface of the leads 102 of the lead frame 106. Another, the molding compound 126 covers the side of the leads 102. In one embodiment, the molding compound 126 fills the through hole 110 formed by the dielectric layer 108 and the solder resist layer 118.

In the above-described package structure and method thereof, the package structure has a dielectric layer 108 connected to the leads 102 and the redistribution layer 116 is formed on the dielectric layer 108, and therefore the package structure is suitable for using the chip 122 having different types of the pad. Besides, the dielectric layer 108 and the redistribution layer 116 formed on the dielectric layer 108 can be instead of the substrate in the pertinent art, such that the chip 122 is electrically connected to the leads 102 via redistribution layer 116. The molding compound 126 fills and uniformly distributes in the space via the through hole 110, and therefore a batter bonding force between the molding compound 126, the chip 122 and the dielectric layer 108 can be increased. Further, the smaller size of the chip can be used in the present invention, so the production cost of the package substrate can be reduced.

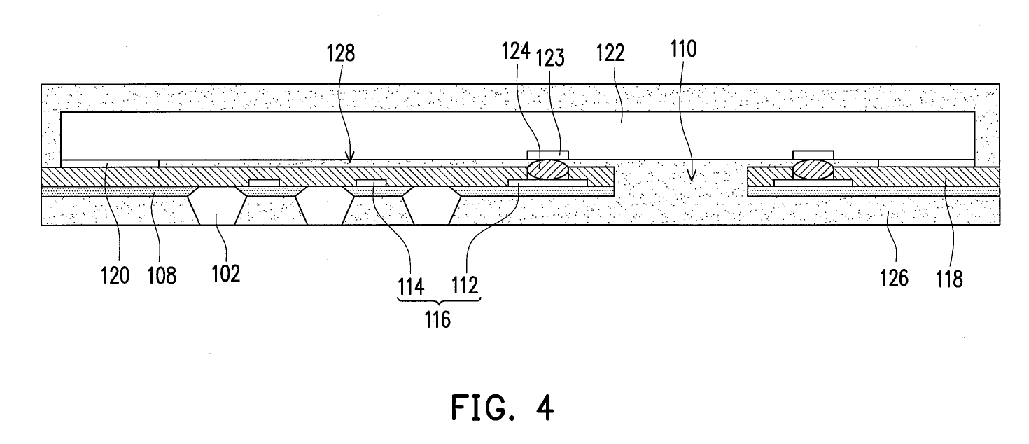

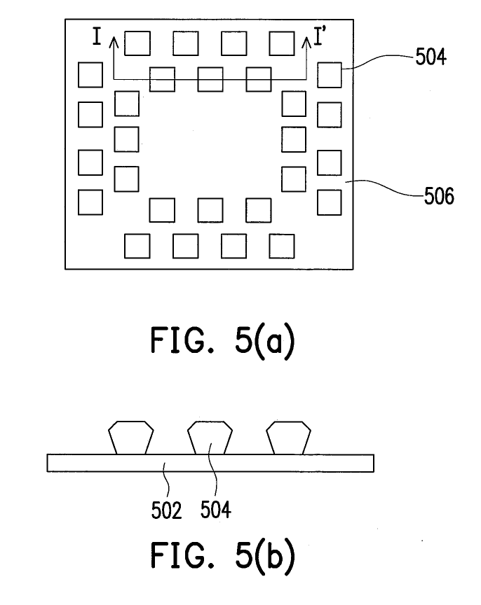

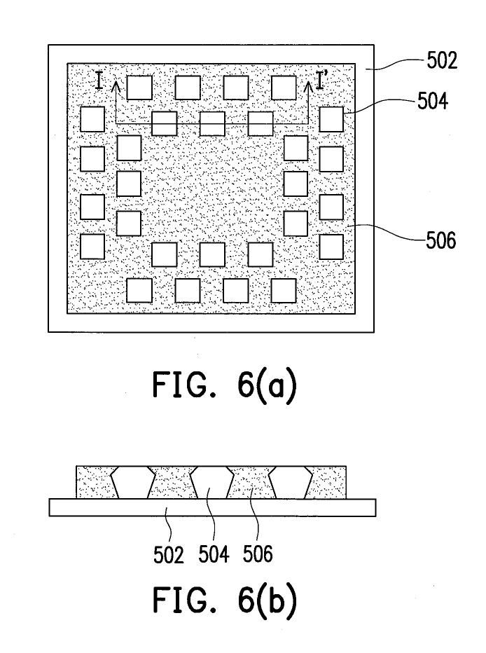

FIGS. 5 through 10 are schematic cross-sectional views illustrating a manufacturing method of a flip chip quad flat non-leaded (QFN) package structure according to an embodiment of the present invention. Herein, the sub-diagrams (a) for FIG. 5 through FIG. 10 are schematic top views of FIG. 5 through FIG. 10. The sub-diagrams (b) for FIG. 5 through FIG. 6 are schematic cross-sectional views depicted in the sub-diagrams (a) for FIG. 5 through FIG. 6 along the line I-I′. The sub-diagrams (b) for FIG. 7 through FIG. 10 are schematic cross-sectional views depicted in the sub-diagrams (a) for FIG. 7 through FIG. 10 along the line II-II′.

As shown in FIGS. 5(a) and 5(b), in a manufacturing method of a flip chip quad flat non-leaded package structure according to the present embodiment, which includes the following steps. A supplementary substrate 502 is provided. A material of the supplementary substrate 502 is, for example, metal and polymer material, wherein the polymer material is a polyimide (PI).

Next, a plurality of leads 504 is formed on the supplementary substrate 502. A material of the leads 504 is, for example, copper, copper alloy, nickel-iron alloy or other applicable metal material. A method of forming the leads 504 includes the following steps. A metallic material layer is provided at first. Next, a patterning process and a photolithography and etching process for once are performed to pattern the metallic material layer, resulting in the required pattern, or a plating or a sputtering process are performed to form the leads 504 on the supplementary substrate 502. In present embodiment, the arrangement of the leads 504 is, for example, an array, a single row, or multiple row of the ring. For the convenience of description, the leads 504 schematically depicted in the present embodiment are arranged in double row of the ring.

Next, referring to FIGS. 6(a) and 6(b), a dielectric layer 506 is formed to cover the supplementary substrate 502 and the leads 504. A material of the dielectric layer 506 is, for example, epoxy resin or other applicable dielectric material. Further, the dielectric layer 506 exposes at least a top surface of the leads 504. The thickness of the dielectric layer 506 is approximate to or equal to the height of the leads 504.

Next, referring to FIGS. 7(a) and 7(b), a redistribution layer 512 is formed on the dielectric layer 506 to change the circuit layout of the external contacts on the chip. The redistribution layer 512 includes a plurality of pads 508 and a plurality of conductive lines 510 connected the pads 508 and the top surface of the leads 504. A method of forming the redistribution layer 512 is, for example, a sputtering process. In the present embodiment, a material of the redistribution layer 512 is, for example, a copper or other applicable metallic material. Moreover, the position and the arrangement of the pads 508 and the conductive lines 510 of the redistribution layer 512 as shown in the FIGS. 7(a) and 7(b) are merely exemplificative and should not be construed as limitations to the present invention.

It should be noted that the dielectric layer 506 and the redistribution layer 512 formed above the dielectric layer 506 in the present embodiment must be capable of the same function of the substrate in the pertinent art. Therefore, the chip adhered for subsequently performing is electrically connected to the leads 504 by the redistribution layer 512.

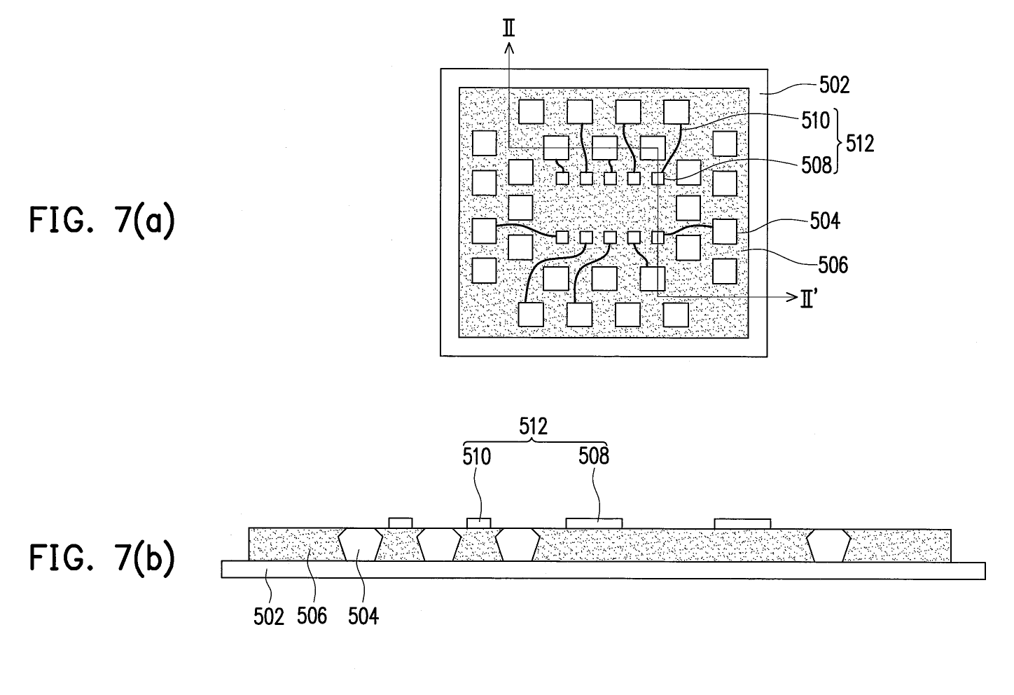

Next, referring to FIGS. 8(a) and 8(b), a solder resist layer 514 is formed to cover the redistribution layer 512, the dielectric layer 506 and the leads 504, and the solder resist layer 514 exposes the surface of the pads 508 of the redistribution layer 512. A material of the solder resist layer 514 is, for example, epoxy resin. A method of forming the solder resist layer 514 is, for example, a coating process.

Next, an adhesive layer 516 is formed on the solder resist layer 514 after forming the solder resist layer 514. A material of the adhesive layer 516 is, for example, epoxy resin, B-stage adhesive or other applicable adhesive material.

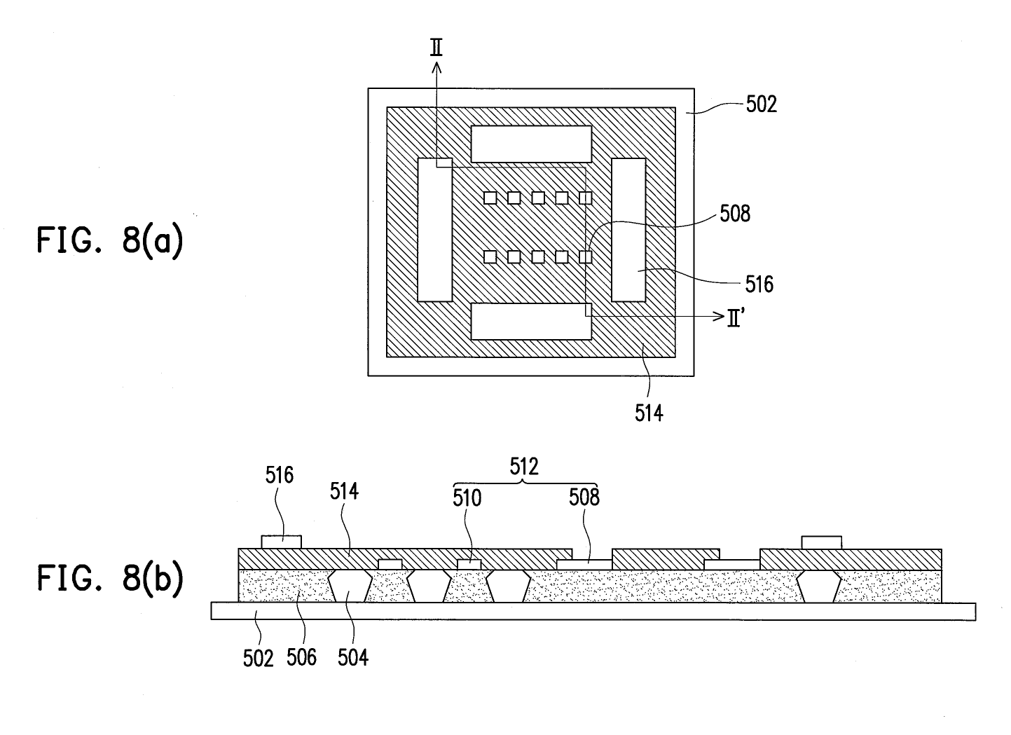

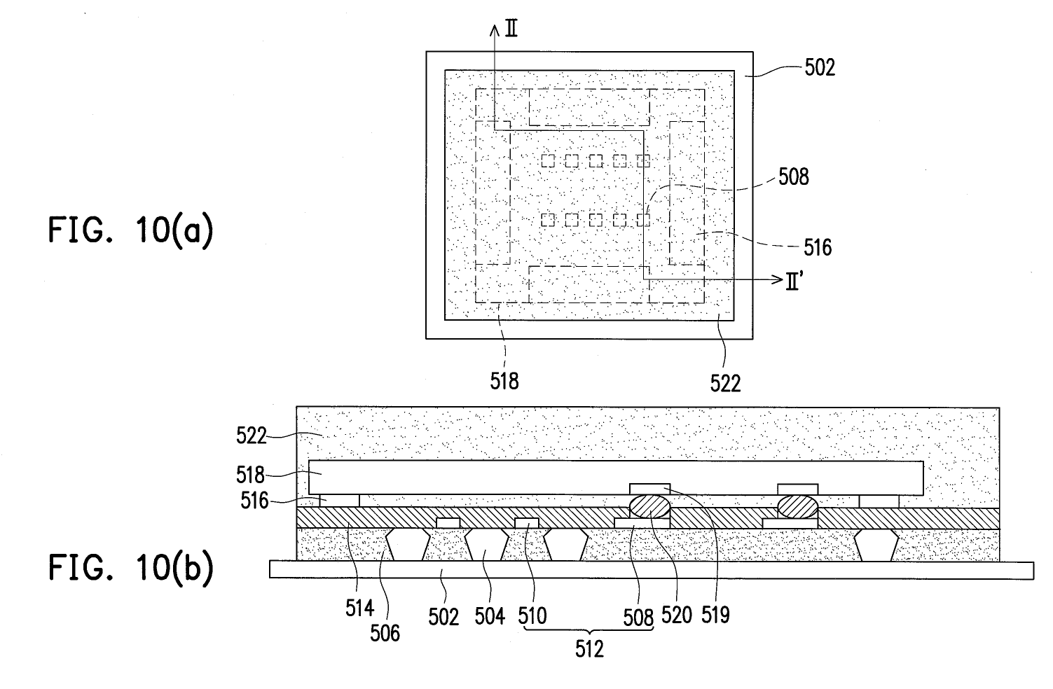

Then, referring to FIGS. 9(a), 9(b) and 11, a chip 518 (as shown in FIG. 11) having the pads 519 disposed on is provided. The distribution of the pads 519 is, for example, peripheral pad or the central pad. In the present embodiment, the exemplificative distribution of the pads 519 merely has the central pad as illustrated in FIG. 11. The chip 518 has a plurality of bumps 520 on the active surface, and each bump 520 is formed on the pads 519 of the chip 518. A material of the bumps 520 is, for example, gold, copper, nickel, aluminium, tin, lead or an alloy of the above-mentioned metals. Furthermore, the chip 518 is flipped such that the active surface is face down. And then, the chip 518 is adhered on the solder resist layer 514 via the adhesive layer 516 and each bump 520 of the chip 518 is electrically connected with one of the pads 508 of the redistribution layer 512.

Specifically, in the present embodiment, the chip 518 can be adhered on the stack structure formed with the solder resist layer 514, the redistribution layer 512, the dielectric layer 506 and the leads 504 via the adhesive layer 516 which is formed on the solder resist layer 514 and has B-stage characteristic. Therefore, the delivery process within the fabrication point is more convenient and the chip-lead frame package structure can be easily and efficiently fabricated. Besides, the chip 518 having different arrangement of the pads can be used in the present invention by using the redistribution layer 512.

Further, in the present embodiment, the package structure is used the flip chip technology instead of the wire bonding of the quad flat non-leaded package in the pertinent art, resulting in reduced package size, namely, reduced the thickness of the package.

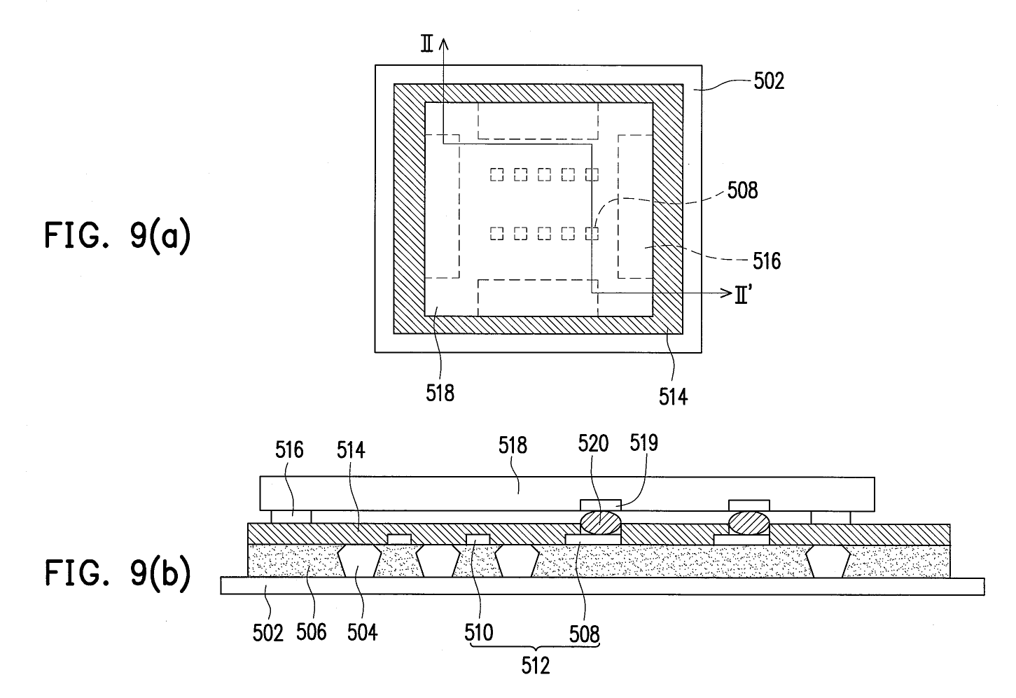

Next, referring to FIGS. 10 (a) and 10 (b), in a manufacturing method of a flip chip quad flat non-leaded package structure according to the present embodiment further includes a molding compound 522. The molding compound 522 covers the chip 518 and the solder resist layer 514. The molding compound 522 is preferred to fill in a space 524 formed by the chip 518 and the solder resist layer 514. A material of the molding compound 522 is, for example, epoxy resin or other applicable polymer material.

Further, in one embodiment, after forming the molding compound 522, the manufacturing method of a flip chip quad flat non-leaded package structure further includes removing the supplementary substrate 502 to expose a bottom surface of the leads 504.

Moreover, since the process of the fabrication has the supplementary substrate 502 design according to the embodiment of the present invention, thereby realizing multiply leads and the array type of the package substrate. Further, since during the subsequent cutting process, the metal layer is not existed in the cutting channels, so that lifespan thereof can be prolonged.

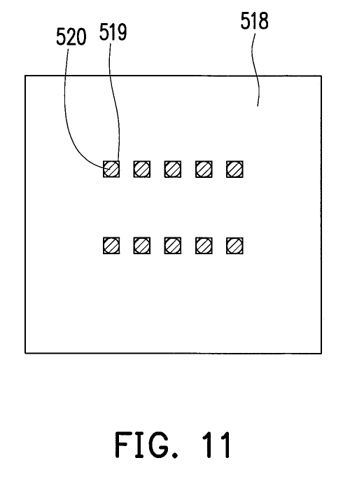

Next, with reference to FIGS. 12, a flip chip quad flat non-leaded package structure in the present invention is formed by the manufacturing method thereof, wherein the material and the manufacturing methods of each of the elements of the package structure have been described above, so the detailed description is not repeated.

In the present embodiment, the package structure includes the dielectric layer 506, the leads 504, the redistribution layer 512, the solder resist layer 514, the adhesive layer 516 and the chip 518 is provided, wherein arrangement of the leads 502 is, for example, an array, a single row, or multiple row of the ring, as shown in FIGS. 5(a) and 5(b). The leads 504 schematically depicted in the present embodiment are arranged in double row of the ring.

Furthermore, the leads 504 are disposed in the dielectric layer 506 and expose the top surface and the bottom surface of the leads 504. The top surface and the bottom surface of the dielectric layer 506 are aligned with the top surface and bottom surface of the leads 504.

Besides, the redistribution layer 512 is disposed on the dielectric layer 506 and the redistribution layer 512 includes a plurality of pads 508 and a plurality of conductive lines 510. The solder resist layer 514 covers the redistribution layer 512, the dielectric layer 506 and the leads 504, and the solder resist layer 514 exposes the surface of the pads 508 of the redistribution layer 512. The adhesive layer 516 is disposed on the solder resist layer 514. The chip 518 has a plurality of bumps 520, and the chip 518 is adhered on the solder resist layer 514 via the adhesive layer 516, and each bump 520 is electrically connected with one of the pads 519 of the redistribution layer 512.

Furthermore, in the flip chip quad flat non-leaded package structure according to the present embodiment further includes a molding compound 522. The molding compound 522 covers the chip 518, the solder resist layer 514 and dielectric layer 506 and fills in a space 524 formed by the chip 518 and the solder resist layer 514.

In the above-described package structure and method thereof, the package structure has a dielectric layer 506 connected to the leads 504 and the redistribution layer 512 is formed on the dielectric layer 506, and therefore the package structure is suitable for using the chip having different types of the pad. Besides, the dielectric layer 506 and the redistribution layer 512 formed on the dielectric layer 506 can be instead of the substrate in the pertinent art, such that the chip 518 is electrically connected to the leads 504 via redistribution layer 512. Moreover, since the process of the fabrication has the supplementary substrate 502 design according to the embodiment of the present invention, thereby realizing multiply leads and the array type of the package substrate. Further, since during the subsequent cutting process, the metal layer is not existed in the cutting channels, so that lifespan thereof can be prolonged.

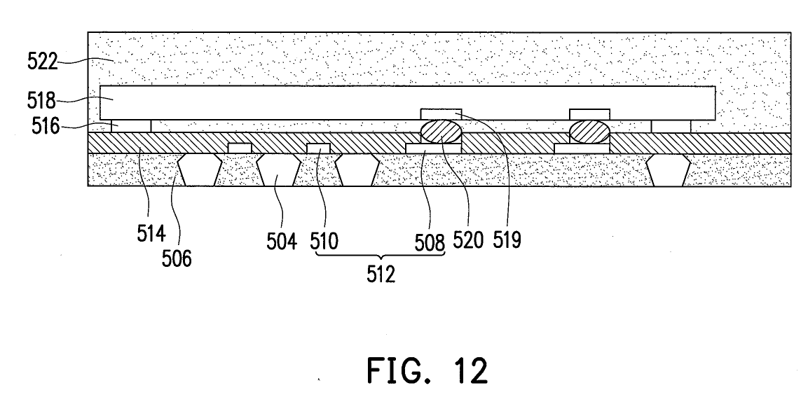

FIG. 13 is a schematic cross-sectional view illustrating a chip package structure according to an embodiment of the present invention. Preferring to FIG. 13, a chip package substrate 1300 including a substrate 1302, a chip 1304, a plurality of bumps 1306, a molding compound 1308 and a plurality of solder ball 1309 is provided. The substrate 1302 has at least an opening 1310, a plurality of pads 1312 and a plurality of ball pads 1314. The pads 1312 and the ball pads 1314 are disposed on the two opposite surface of the substrate 1302 respectively. The chip 1304 has an active surface and a plurality of pads 1316 disposed on the active surface. The active surface of the chip 1304 is face to the substrate 1302. Namely, the chip 1304 is disposed on the substrate 1302 by using a flip-chip bonding. The bumps 1306 are disposed between the pads 1312 and the pads 1316 and connect to the pads 1312 and the pads 1316. Namely, the chip 1304 is electrically connected to the substrate 1302 via the bumps 1306. A method of forming the bumps 1306 is, for example, using the wiring bonding process to form the stub bump, using the plating to form the metallic bump or using coating, screen printing or other method to form the colloid bumps containing metal.

Furthermore, an adhesive layer 1318 is selectively disposed between the chip 1304 and the substrate 1302 and surrounds the bumps 1306. A material of the adhesive layer 1318 is, for example, B-stage adhesive. The solder balls 1309 are disposed on the ball pads 1314 respectively. The molding compound 1308 covers the chip 1304 and the bumps 1306, the pads 1312, the pads 1316 and the adhesive layer 1318 and fills the opening 1310. A material of the molding compound 1308 is, for example, an epoxy resin. To be more specific, during the process for forming the molding compound 1308, the molding compound 1308 not only directly covers in the substrate 1302, but also passes through the through hole 1310 and enters a space between the chip 1301 and substrate 1302 to cover the bumps 1306, the pads 1312 and the pads 1316, resulting in increased the contact area between the molding compound 1308 and the substrate 1302, and improved the reliability.

In the above-described package substrate, the chip 1304 is disposed on the substrate 1302 by using a flip-chip bonding, and the chip 1304 is electrically connected to the substrate 1302 via the bumps 1306. Namely, the chip 1304 and the bumps 1306 are located in the same side of the substrate 1302, and therefore the electrically connected route between the chip 1304 and the substrate 1302 is reduced, and the transmitting rate between the chip 1304 and the substrate 1302 is improved.

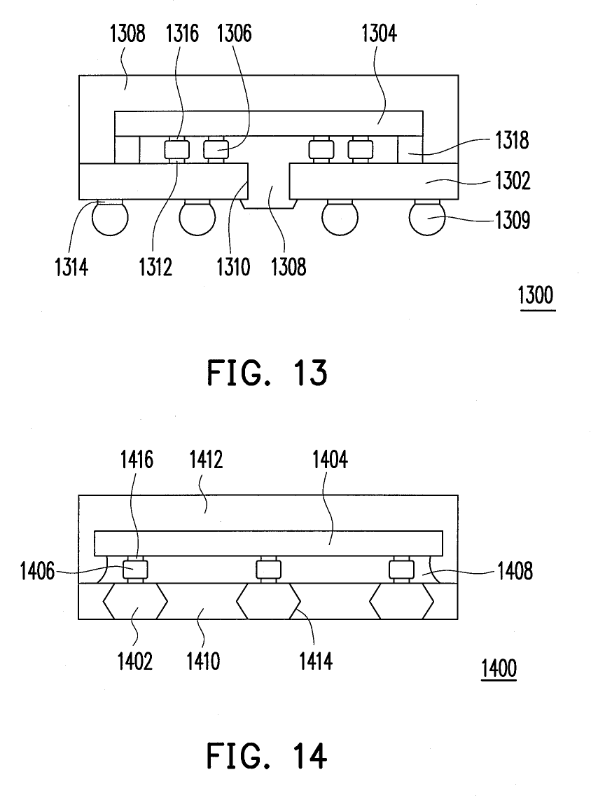

FIG. 14 is a schematic cross-sectional view illustrating a chip package structure according to another embodiment of the present invention. Referring to FIG. 14, a chip package substrate 1400 including a lead frame comprising a plurality of leads 1402, a chip 1404, a plurality of bumps 1406, an adhesive layer 1408, a first molding compound 1410 and a second molding compound 1412 is provided. A material of the first molding compound 1410 is the same or different to a material of the second molding compound 1412. The lead frame comprising a plurality of leads 1402 has at least an opening 1414 between the leads 1402. The chip 1404 has an active surface and a plurality of pads 1416 disposed on the active surface. The active surface of the chip 1404 is face to the leads 1402. In the other words, the chip 1404 is disposed on the lead frame comprising a plurality of leads 1402 by using a flip-chip bonding. The bumps 1406 are disposed between the pads 1416 and the leads 1402, and connect the pads 1416 and the leads 1402. In the other words, the chip 1404 is electrically connected to the leads 1402 via the bumps 1406. The present embodiment is partially similar to the embodiment as shown in FIG. 13, the chip 1404 is disposed on the lead frame comprising a plurality of leads 1402 by using a flip-chip bonding, and the chip 1404 is electrically connected to the leads 1402 via the bumps 1406 which are between the chip 1404 and the leads 1402. Namely, the chip 1404 and the contact points of the leads 1402 are located in the same side of the lead frame comprising a plurality of leads 1402, and therefore the electrically connected route between the chip 1404 and the leads 1402 is reduced, and the transmitting rate between the chip 1404 and the lead frame comprising a plurality of leads substrate 1402 is improved.

Furthermore, an adhesive layer 1408 is selectively disposed between the chip 1404 and the leads 1402 and covers the bumps 1406 and the pads 1416. The first molding compound 1410 is disposed in the opening 1414, and the second molding compound 1412 covers the chip 1404 and the adhesive layer 1408. To be more specific, during the process for forming the chip package substrate 1400 includes the following steps. The first molding compound 1410 is formed in the opening 1414 of the leads 1402 at first. Next, the chip 1404 is electrically connected to the leads 1402. Next, the adhesive layer 1408 is formed between the chip 1404 and the lead frame comprising a plurality of leads 1402. Since the first molding compound 1410 is formed in the opening 1414, so that the adhesive layer 1408 leaking from the opening 1414 can be avoided. After that, the second molding compound 1412 is formed on the lead frame comprising a plurality of leads 1402 and covers the chip 1404 and adhesive layer 1408. So far, the chip package structure 1400 is roughly formed. In the present embodiment, the material of the first molding compound 1410 and the second molding compound 1412 are, for example, epoxy resin.

In the present invention, the contact points for connected the chip and the substrate (or the lead frame comprising a plurality of leads) are disposed in the same side of the substrate (or the lead frame comprising a plurality of leads), and the chip is electrically connected to the substrate (or the lead frame comprising a plurality of leads) via the bumps, and therefore the electrically connected route between the chip and the substrate (or the lead frame comprising a plurality of leads) is reduced, the transmitting rate between the chip and the substrate (or the lead frame comprising a plurality of leads) is improved, and the efficiency of the devices are enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of a flip chip quad flat non-leaded package structure, comprising:
providing a lead frame having a plurality of leads;
forming a dielectric layer on the lead frame, wherein the dielectric layer exposes a top surface and a bottom surface of the leads;
forming a redistribution layer on the dielectric layer, wherein the redistribution layer includes a plurality of pads and a plurality of conductive lines connected the pads and the top surface of the leads;
forming a solder resist layer to cover the redistribution layer, the dielectric layer and the leads, and expose the surface of the pads;
forming an adhesive layer on the solder resist layer;
proving a chip, wherein the chip has a plurality of bumps; and
adhering the chip on the solder resist layer via the adhesive layer so that each bump is electrically connected with one of the pads.

2. The manufacturing method of the flip chip quad flat non-leaded package structure as claimed in claim 1, further comprises forming a molding compound to cover the chip, the solder resist layer and the dielectric layer and fill a space formed by the chip and the solder resist layer, wherein the molding compound exposes the bottom surface of the leads.

3. The manufacturing method of the flip chip quad flat non-leaded package structure as claimed in claim 2, wherein the molding compound covers the side of the leads.

4. The manufacturing method of the flip chip quad flat non-leaded package structure as claimed in claim 2, further comprising:
forming at least a through hole in the dielectric layer;
forming the pads of the redistribution layer around the through hole; and
exposing the through hole in the solder resist layer.

5. The manufacturing method of the flip chip quad flat non-leaded package structure as claimed in claim 4, further comprising filling the through hole with the molding compound.

6. The manufacturing method of the flip chip quad flat non-leaded package structure as claimed in claim 1, wherein a material of the adhesive layer comprises epoxy resin or B-stage adhesive.

7. The manufacturing method of the flip chip quad flat non-leaded package structure as claimed in claim 1, wherein the thickness of the dielectric layer is smaller than or equal to the height of the leads.

8. The manufacturing method of the flip chip quad flat non-leaded package structure as claimed in claim 1, wherein the lead frame further comprises a frame, and the leads are connected with the frame and arranged along the center of the frame and extending to an array or a single row.

9. A flip chip quad flat non-leaded package structure, comprising:
a dielectric layer;
a plurality of the leads, disposed in the dielectric layer and exposing a top surface and a bottom of the leads;
a redistribution layer, disposed on the dielectric layer, wherein the redistribution layer includes a plurality of pads and a plurality of conductive lines connected the pads and the top surface of the leads;
a solder resist layer, covering the redistribution layer, the dielectric layer and the leads, and exposing the surface of the pads;
an adhesive layer, disposed on the solder resist layer; and
a chip, having a plurality of bumps, wherein the chip is adhered on the solder resist layer via the adhesive layer, and each bump is electrically connected with one of the pads.

10. The flip chip quad flat non-leaded package structure as claimed in claim 9, further comprises:
a molding compound, covering the chip, the solder resist layer and the dielectric layer and filling a space formed by the chip and the solder resist layer, an exposing the bottom surface of the leads.

11. The flip chip quad flat non-leaded package structure as claimed in claim 10, wherein the molding compound covers the side of the leads.

12. The flip chip quad flat non-leaded package structure as claimed in claim 10, wherein the dielectric layer has at least a through hole, and the solder resist layer exposes the through hole.

13. The flip chip quad flat non-leaded package structure as claimed in claim 12, further comprising the molding compound disposed in the through hole.

14. The flip chip quad flat non-leaded package structure as claimed in claim 9, wherein the surface of the dielectric layer is aligned with the top surface of the leads, and the thickness of the dielectric layer is smaller than or equal to the height of the leads.

15. The flip chip quad flat non-leaded package structure as claimed in claim 9, further comprises a frame, wherein the leads are connected with the frame and arranged along the center of the frame and extending to an array or a single row.

16. A manufacturing method of a flip chip quad flat non-leaded package structure, comprising:
providing a supplementary substrate;
forming a plurality of leads on the supplementary substrate;
forming a dielectric layer to cover the supplementary substrate and expose at least a top surface of the leads;
forming a redistribution layer on the dielectric layer, wherein the redistribution layer includes a plurality of pads and a plurality of conductive lines connected the pads and the top surface of the leads;
forming a solder resist layer to cover the redistribution layer, the dielectric layer and the leads, and expose the surface of the pads;
forming an adhesive layer on the solder resist layer;
proving a chip, wherein the chip has a plurality of bumps; and
adhering the chip on the solder resist layer via the adhesive layer so that each bump is electrically connected with one of the pads.

17. The manufacturing method of the flip chip quad flat non-leaded package structure as claimed in claim 16, further comprises forming a molding compound to cover the chip and the solder resist layer and fill a space formed by the chip and the solder resist layer.

18. The manufacturing method of the flip chip quad flat non-leaded package structure as claimed in claim 17, further comprises removing the supplementary substrate to expose a bottom surface of the leads.

19. The manufacturing method of the flip chip quad flat non-leaded package structure as claimed in claim 16, wherein a material of the supplementary substrate comprises polymer material or metal.

20. The manufacturing method of the flip chip quad flat non-leaded package structure as claimed in claim 16, wherein the thickness of the dielectric layer is approximate to or equal to the height of the leads.

21. A flip chip quad flat non-leaded package structure, comprising:
a dielectric layer;
a plurality of the leads, disposed in the dielectric layer and exposing a top surface and a bottom of the leads;
a redistribution layer, disposed on the dielectric layer, wherein the redistribution layer includes a plurality of pads and a plurality of conductive lines connected the pads and the top surface of the leads;
a solder resist layer, covering the redistribution layer, the dielectric layer and the leads, and exposing the surface of the pads;
an adhesive layer, disposed on the solder resist layer; and
a chip, having a plurality of bumps, wherein the chip is adhered on the solder resist layer via the adhesive layer, and each bump is electrically connected with one of the pads.

22. The flip chip quad flat non-leaded package structure as claimed in claim 21, further comprises:
a molding compound, covering the chip and the dielectric layer and disposed in a space formed by the chip and the solder resist layer.

23. The flip chip quad flat non-leaded package structure as claimed in claim 21, wherein the top surface and the bottom surface of the dielectric layer is aligned with the top surface and the bottom surface of the leads.

24. The flip chip quad flat non-leaded package structure as claimed in claim 21, wherein the leads are arranged in at least a ring.

25. The flip chip quad flat non-leaded package structure as claimed in claim 21, wherein the leads are arranged in an array.

26. The flip chip quad flat non-leaded package structure as claimed in claim 21, wherein a material of the adhesive layer comprises epoxy resin or B-stage adhesive.

27. A chip package structure, comprising:
a substrate, having at least an opening, a plurality of first pads and a plurality of ball pads, wherein the first pads and the ball pads are disposed on the two opposite surface of the substrate respectively;
a chip, having an active surface and a plurality of second pads disposed on the active surface, wherein the active surface of the chip is face to the substrate;
a plurality of the bumps, disposed between the first pads and the second pads and connected to the first pads and the second pads; and
a molding compound, covering the chip and the bumps and filling the opening.

28. The chip package structure as claimed in claim 27, further comprises an adhesive layer disposed between the chip and the substrate and surrounding the bumps.

29. The chip package structure as claimed in claim 28, wherein a material of the adhesive layer comprises B-stage adhesive.

30. The chip package structure as claimed in claim 27, further comprises a plurality of solder balls, disposed on the ball pads respectively.

31. A chip package structure, comprising:
a lead frame comprising a plurality of leads, having at least a opening between the leads;
a chip, having an active surface and a plurality of pads disposed on the active surface, wherein the active surface of the chip is face to the leads;
a plurality of the bumps, disposed between the pads and the leads and connected to the pads and the leads;
an adhesive layer, disposed between the leads and the chip and covering the bumps;
a first molding compound, disposed in the opening; and
a second molding compound, covering the chip and the adhesive layer.

32. The chip package structure as claimed in claim 31, wherein a material of the adhesive layer comprises B-stage adhesive.
